(19) United States
(12) Patent Application Publication
(10) Pub. No.: US 2003/0030126 A1
(43) Pub. Date: Feb. 13, 2003

(54) Bipolar transistor and manufacturing method therefor

(75) Inventor: Fumihiko Hirose, Yokohama (JP)

Correspondence Address: ARMSTRONG,WESTERMAN & HATTORI, LLP, 1725 K STREET, NW., SUITE 1000, WASHINGTON, DC, 20006, US

(73) Assignee: Mitsubishi Heavy Industries, Ltd., Tokyo (JP)

(21) Appl. No.: 09/995,576

(22) Filed: Nov. 29, 2001

(30) Foreign Application Priority Data
Jun. 22, 2001 (JP) 2001-189275

(51) Int. Cl. H01L 27/082

(52) U.S. Cl. 257/565

(57) ABSTRACT

A bipolar transistor has a first conductivity type semiconductor substrate (1), a first conductivity type collector layer (2) with an impurity concentration lower than that of the semiconductor substrate (1), which is formed on the semiconductor substrate (1), a second conductivity type base layer (3) formed on the collector layer (2), a first conductivity type emitter layer (4) formed on the base layer (3), and a conductive film (8) covering the side faces of the collector layer (2) and the base layer (3). Since the conductive film (8) covering the side faces of the collector layer (2) and the base layer (3) is provided, the electric field concentration near the side faces of the collector layer (2) and the base layer (3) is relaxed, so that the withstand voltage of transistor can be increased. Also, the thickness of the collector layer (2) is decreased, so that the current amplification factor can be enhanced.

### FIELD OF THE INVENTION AND RELATED ART STATEMENT

The present invention relates to a bipolar transistor and a manufacturing method therefor and, more particularly, to a bipolar transistor used for a high-power switch and a manufacturing method therefor.

A bipolar transistor has been used widely as a high-power electronic switch. For the bipolar transistor, a second conductivity type (for example, p-type) semiconductor is brought into contact with a first conductivity type (for example, n-type) semiconductor, and further a first conductivity type semiconductor is brought into contact with the second conductivity type semiconductor, each of these semiconductors being used as a base, an emitter, and a collector.

FIG. 4 is a circuit diagram showing a switch circuit using a bipolar transistor. In this switch circuit, a load 31 and a power source 32 connected serially are connected to a collector terminal 35 and an emitter terminal 34 of a bipolar transistor 30. A base current (Ib) is caused to flow from a base terminal 33 to the emitter terminal 34, and a collector current (Ic) flowing from the collector terminal 35 to the emitter terminal 34 is changed.

In this case, when the base current Ib=0, the collector current Ic=0. Therefore, a high impedance state is established between the collector and the emitter, and thus the bipolar transistor becomes in an off state. On the other hand, if the base current Ib is increased to a predetermined value, a low impedance state is established between the collector and the emitter, and thus the bipolar transistor 30 becomes in an on state.

FIG. 5 is a sectional view of a mesa type bipolar transistor used as such a high-power switch. The mesa type bipolar transistor is configured as an npn⁻n⁺ type transistor by successively stacking an n-type (n⁻) semiconductor layer 2 with a low impurity concentration, p-type semiconductor layer 3, and an n-type semiconductor layer 4 on an n-type (n⁺) semiconductor substrate 1 with a high impurity concentration. In this case, the n-type semiconductor substrate 1 and the n-type semiconductor layer 2 function as a collector, the p-type semiconductor layer 3 as a base, and the n-type semiconductor layer 4 as an emitter.

The n-type semiconductor layer 4 (hereinafter referred to as an emitter layer 4) is formed into a comb teeth shape on the p-type semiconductor layer 3 (hereinafter referred to as a base layer 3), and an emitter electrode 5 and a base electrode 6 are formed in a portion in which the emitter layer 4 and the base layer 3 are exposed to the outside, respectively. Also, a collector electrode 7 is formed on the back of the n-type semiconductor substrate 1. In FIG. 5, the side wall of the n-type semiconductor layer 2 (hereinafter referred to as a collector layer 2) is formed so as to make an angle θ with the n-type semiconductor substrate 1.

FIG. 6 shows an example of an impurity concentration profile of the high-power bipolar transistor shown in FIG. 5. The abscissas represent a depth from the interface between the emitter electrode 5 and the emitter layer 4, and the ordinates an impurity concentration.

Usually, the impurity concentration of the emitter layer 4 is set at 10¹⁹/cm³ or higher, and the impurity concentration of the base layer 3 is set at about 10¹⁷ to 10¹⁸/cm³. Also, the width of the base layer 3 is set at 1.0 μm or smaller to prevent the switching speed and current amplification factor from decreasing. On the other hand, the impurity concentration of the collector layer 2 is set at 10¹⁵/cm³ or lower, and the width thereof is set so as to increase as the required withstand voltage increases.

On the other hand, for such a mesa type high-power bipolar transistor, as described in IEEE Transactions on Electron Devices, 1964, vol. ED-11, p. 313, when a voltage is applied to between the emitter and the collector, an electric field concentrates on the side wall of the collector layer 2. In this case, a ratio of the electric field intensity Ee on the side wall of the collector layer 2 to the electric field intensity Ec within the collector layer 2 (Ee/Ec) depends on the angle θ between the side wall of the collector layer 2 and the semiconductor substrate 1, and when the angle θ is close to 90 degrees, Ee/Ec is about 2.

FIG. 7 is a sectional view showing a potential distribution of a mesa type high-power bipolar transistor. In FIG. 7, a depletion layer region 11 in the collector layer 2 and the base layer 3 is indicated by hatching, and equipotential distribution curve 41 is indicated by a dotted line.

As described above, for the mesa type high-power bipolar transistor, since the electric field intensity Ee in an electric field concentration portion on the side wall of the collector layer 2 is about two times the electric field intensity Ec within the collector layer 2, the thickness and resistivity value of the collector layer 2 are set so that dielectric breakdown (avalanche breakdown) does not occur in the side wall portion of the collector layer 2. For example, if an emitter-collector withstand voltage of 500 V is required, the thickness and resistivity value of the collector 2 are set so that avalanche breakdown does not occur even at 1000 V, which is the double of 500 V.

Generally, a voltage at which avalanche breakdown occurs in the depletion layer region 11 is called a theoretical withstand voltage. The voltage capable of being applied actually to a transistor is lower than the theoretical withstand voltage because an electric field concentration occurs on the surface of side wall of the transistor, which leads to withstand voltage breakdown. For the mesa type bipolar transistor, since an electric field whose intensity is two times that in the collector layer is applied onto the side wall of the collector layer as described above, about a half of the theoretical withstand voltage is an actual withstand voltage.

Thus, for the mesa type high-power bipolar transistor, the thickness of the collector layer 2 is set from the viewpoint of withstand voltage. However, the increase in thickness of the collector layer 2 decreases the current amplification factor due to the Kirk effect. In particular, if the mesa type bipolar transistor is operated at a low voltage with a high current, the current amplification factor decreases significantly.

The Kirk effect, which is also called a base spreading effect, is a phenomenon that the ratio of recombination current to the base current increases, and the ratio of base-emitter injection current contributing to amplification decreases, by which the current amplification factor is decreased.

FIG. 8 shows the carrier distribution in a transistor at the time when the Kirk effect is brought about. When the bipolar transistor is turned on to cause a current to flow from the collector layer 2 to the emitter layer 4, electrons in the emitter layer 4 go through the base layer 3 and flow into the n⁻ collector layer 2, and holes flow from the base layer 3 into the collector layer 2 so that the electric charge in the collector layer 2 becomes neutral.

At the time when the Kirk effect is brought about, the ratio of recombination current to the base current increases, and the ratio of base-emitter injection current contributing to amplification decreases, with the result that the current amplification factor decreases. In this case, if the thickness of the collector layer 2 is increased, the recombination region increases and thus the ratio of recombination current increases, so that the current amplification factor decreases further.

Thus, for the conventional high-power bipolar transistor, it is difficult to increase both withstand voltage and current amplification factor at the same time. Specifically, if the thickness of the collector layer 2 is increased to improve the withstand voltage, the current amplification undesirably decreases due to the Kirk effect. Conventionally, therefore, contrivance has been made to secure a necessary withstand voltage while the current amplification factor is increased by decreasing the thickness of the collector layer 2.

FIG. 9 is a sectional view of a conventional transistor in which an electric field around the collector layer 2 is relaxed by using a guard ring to secure a necessary withstand voltage. In this example, the transistor has no mesa structure, that is, the collector layer 2 is extended around the transistor, and a ring-shaped guard ring 50 formed of, for example, a p-type semiconductor is disposed on the surface of the collector layer 2. It has been reported that in this case, by making the guard ring 50 have a predetermined potential, the electric field concentration in this portion can be restrained, so that the actual withstand voltage becomes about 80% of the theoretical withstand voltage.

Also, FIG. 10 is a sectional view of a conventional transistor in which a semi-insulating film 51 is disposed at the outer periphery of the transistor to relax the electric field concentration. In this example, by disposing the semi-insulating film 51 at the outer periphery of the transistor, the electric field concentration around the transistor is relaxed, by which a necessary withstand voltage can be secured.

Thus, in the conventional transistor shown in FIG. 9 or 10, a decrease in current amplification factor is prevented by decreasing the thickness of the collector layer 2, and a necessary withstand voltage is secured by relaxing the electric field concentration by means of the guard ring 50 or the semi-insulating film 51.

However, the above-described guard ring 50 or the semi-insulating film 51 must be formed in the outer peripheral portion of the transistor so as to have a width of about 100 to 1000 μm. Therefore, when the transistor is cut out as a chip, the effective area operating as a transistor decreases, which presents a drawback in that the maximum current capable of being switched decreases.

On the other hand, in the process for manufacturing the conventional transistor as well, the effective area operating as a transistor decreases, which presents a drawback in that the maximum current capable of being switched decreases.

FIG. 11 is an explanatory view of the conventional process for manufacturing a transistor. In the conventional process for manufacturing a transistor, a plurality of transistor portions 21 are first formed in an array form on a wafer as shown in FIG. 11(a), and next, a mesa groove 60 is formed around each of the transistor portions 21 by chemical etching as shown in FIG. 11(b).

The mesa groove 60 is formed to prevent the influence of a dicing groove 61 formed in the next process from being exerted on the transistor portion 21. Specifically, since the surface of the dicing groove 61 is metalized by defects and crystalline metamorphism, the base layer 3 and the collector layer 2 conduct to each other and thus a leakage current increases in the off state of the transistor without the mesa groove 60 around the transistor portion 21.

Next, a dicing groove 61 is formed on the outside of the mesa groove 60 by using a rotary grinder as shown in FIG. 11(c), and the transistor portion 21 is cut out as shown in FIG. 11(d). The mesa groove 60 and the dicing groove 61 are spaced about 100 μm apart from each other to provide a buffer region. This is also done to prevent the influence of the dicing groove 61 from being exerted on the transistor portion 21.

Thus, in the conventional process for manufacturing a transistor, the mesa groove 60 must be formed around the transistor portion 21, which decreases the effective area of the transistor portion 21, resulting in a decrease in the maximum current capable of being switched.

### OBJECT AND SUMMARY OF THE INVENTION

Accordingly, an object of the present invention is to provide a high-power bipolar transistor capable of increasing both of the current amplification factor and the withstand voltage and increasing the maximum current capable of being switched, and a manufacturing method for the bipolar transistor.

To achieve the above object, one aspect of the present invention is characterized by having a conductive film covering the side faces of a collector layer and a base layer in a mesa type bipolar transistor. According to the present invention, the electric field concentration can be relaxed by the conductive film, so that the withstand voltage of transistor can be increased. Also, since the thickness of the collector layer can be decreased, the current amplification factor can be enhanced. Further, since the conductive film is formed on the side face of transistor, the effective area of transistor is increased, so that the maximum current capable of being switched can be increased.

Also, to achieve the above object, another aspect of the present invention is characterized by having a first conductivity type semiconductor substrate, a first conductivity type collector layer with an impurity concentration lower than that of the semiconductor substrate, which is formed on the semiconductor substrate, a second conductivity type base layer formed on the collector layer, a first conductivity type emitter layer formed on the base layer, and a conductive film covering the side faces of the collector layer and the base layer.

According to the present invention, since the conductive film covering the side faces of the collector layer and the base layer is provided, the electric field concentration near the side faces of the collector layer and base layer is relaxed, so that the withstand voltage of transistor can be increased. Also, since the thickness of the collector layer can be decreased, the current amplification factor can be enhanced.

Also, as a preferred mode of the above-described invention, the side faces of the collector layer and base layer may be at an angle of approximately 90 degrees with the interface between the collector layer and the semiconductor substrate.

According to the present invention, since the side faces of the collector layer and base layer may be at an angle of approximately 90 degrees with the interface between the collector layer and the semiconductor substrate, the effective area of transistor is increased, so that the maximum current capable of being switched can be increased.

Also, to achieve the above object, still another aspect of the present invention is characterized by forming a first conductivity type collector layer with an impurity concentration lower than that of a first conductivity type semiconductor substrate, a second conductivity type base layer, and a first conductivity type emitter layer on the surface of the first conductivity type semiconductor substrate; forming a plurality of sets of a base electrode and an emitter electrode at intervals on the base layer and emitter layer; forming separation grooves in the semiconductor substrate between the adjacent sets of the base electrode and emitter electrode from the back side of the semiconductor substrate; and separating the sets of the base electrode and emitter electrode from each other along the separation groove.

According to the present invention, since the separation grooves are formed within the semiconductor substrate from the back side of the semiconductor substrate to separate a set of the base electrode and the emitter electrode along the separation groove, the metamorphism due to the separation groove formed by a grinder or the like does not affect the collector layer, base layer, and emitter layer. Therefore, there is no need for forming a region for avoiding the metamorphism due to the separation groove at the outer periphery of the transistor. As a result, the effective area of transistor is increased, so that the maximum current capable of being switched can be increased.

### BRIEF DESCRIPTION OF THE DRAWINGS

FIG. 1 is a sectional view of a high-power bipolar transistor in accordance with an embodiment of the present invention;

FIG. 2 is a sectional view showing an equivalent resistance of a transistor;

FIG. 3 is an explanatory view of a process for manufacturing a high-power bipolar transistor in accordance with an embodiment of the present invention;

FIG. 4 is a circuit diagram showing a switch circuit using a bipolar transistor;

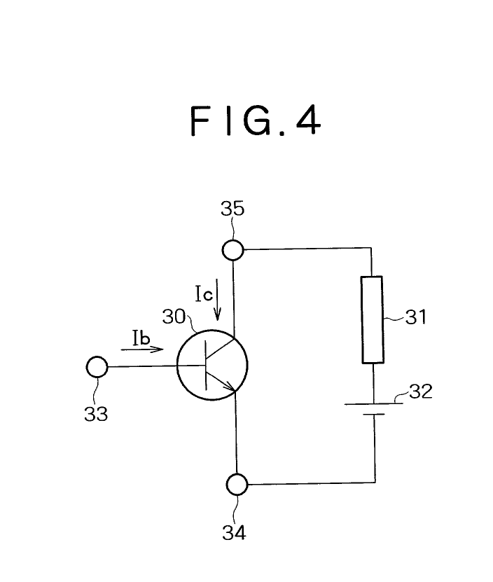

FIG. 5 is a sectional view of a conventional high-power bipolar transistor;

FIG. 6 is a diagram showing a dope concentration profile of a conventional high-power bipolar transistor;

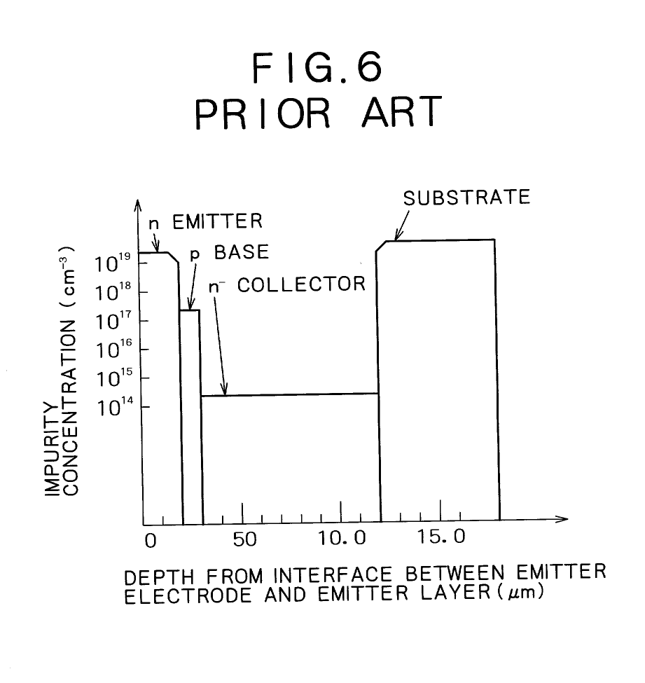

FIG. 7 is a sectional view showing a potential distribution of a conventional high-power bipolar transistor;

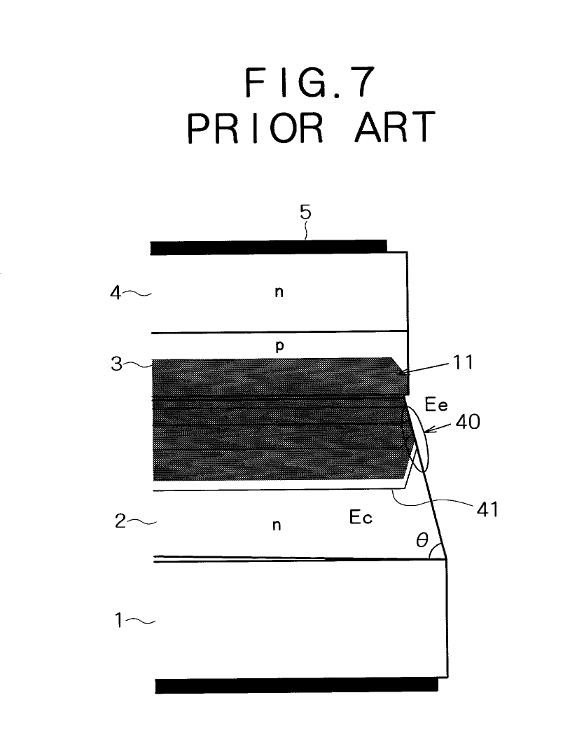

FIG. 8 is a diagram showing the carrier distribution in a transistor at the time when the Kirk effect is brought about;

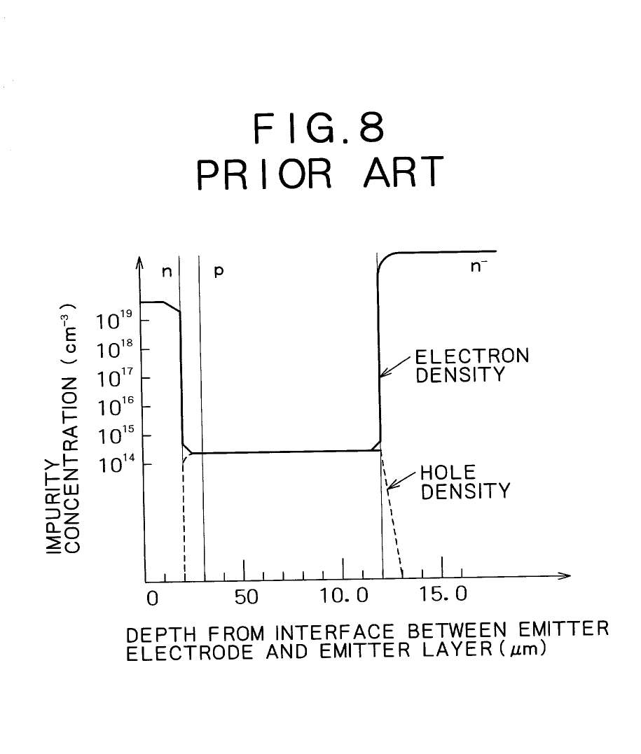

FIG. 9 is a sectional view of a transistor in which an electric field at the outer periphery of the transistor is relaxed by using a guard ring;

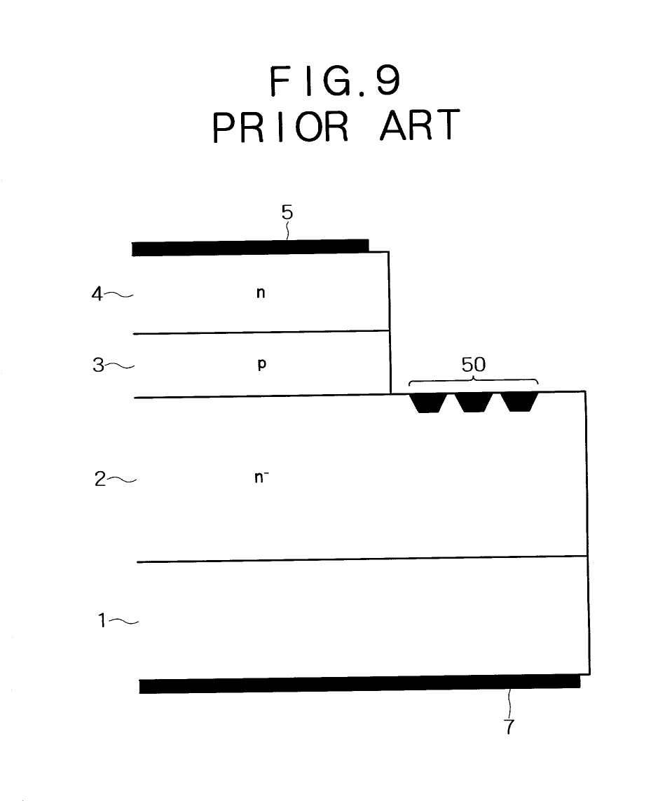

FIG. 10 is a sectional view of a transistor in which the electric field concentration at the outer periphery of the transistor is relaxed by using a semi-insulating film; and

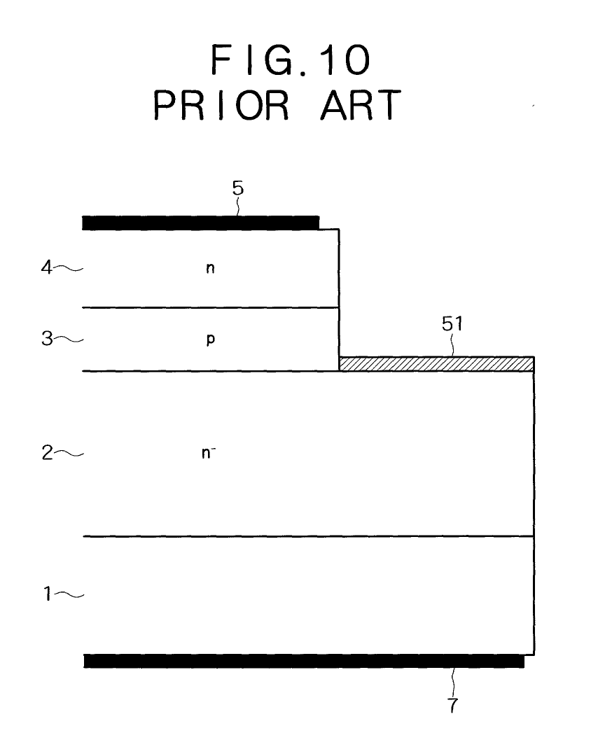

FIG. 11 is an explanatory view of a conventional process for manufacturing a high-power bipolar transistor.

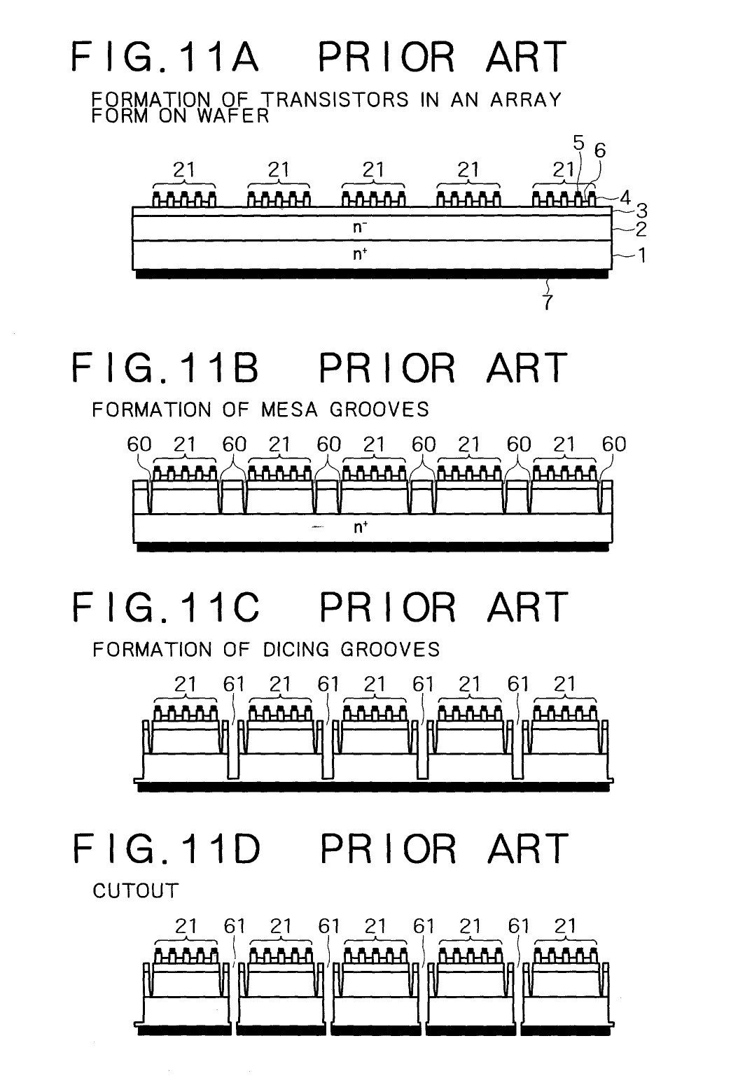

### DETAILED DESCRIPTION OF PREFERRED EMBODIMENTS

Embodiments of the present invention will now be described with reference to the accompanying drawings. However, the embodiments described below do not limit the technical scope of the present invention.

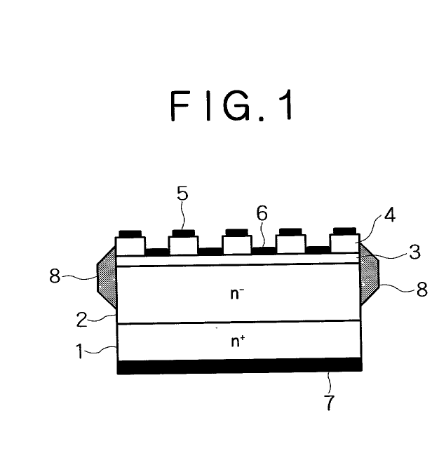

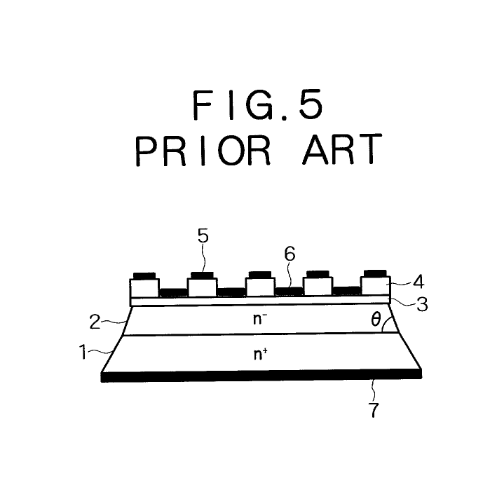

FIG. 1 is a sectional view of a mesa type high-power bipolar transistor in accordance with an embodiment of the present invention. In FIG. 1, the same reference numerals are applied to elements common to those shown in FIG. 5. The high-power bipolar transistor of this embodiment is constructed by successively stacking a collector layer 2 of an n-type (n⁻) semiconductor with a low impurity concentration, a base layer 3 of a p-type semiconductor, and an emitter layer 4 of an n-type semiconductor on an n-type (n⁺) semiconductor substrate 1 with a high impurity concentration. Also, a conductive film 8 formed of amorphous silicon with a resistivity of, for example, about several hundred ohm·centimeters is formed in the side wall portion of the transistor.

The emitter layer 4 is formed into a comb teeth shape on the base layer 3, and an emitter electrode 5 and a base electrode 6 are formed in a portion in which the emitter layer 4 and the base layer 3 are exposed to the outside. Also, a collector electrode 7 is formed on the back of the n-type semiconductor substrate 1.

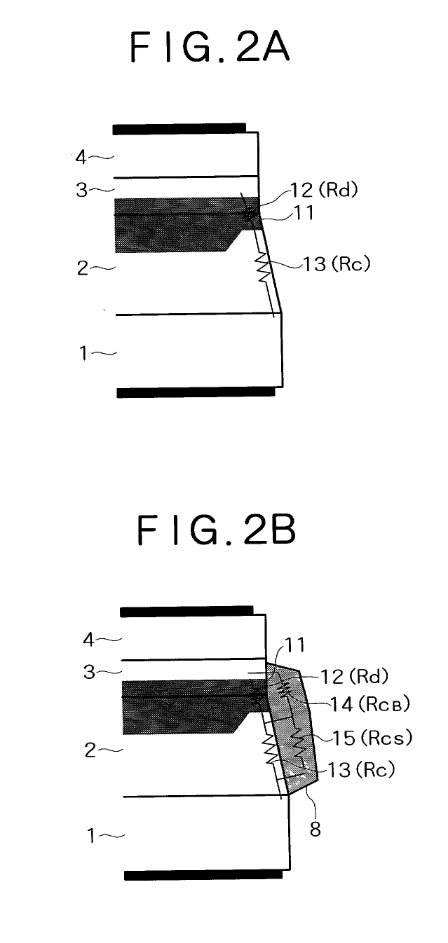

For the high-power bipolar transistor of this embodiment, the electric field concentration on the side wall of transistor is relaxed by the conductive film 8. This fact will be explained with reference to FIG. 2. FIG. 2(a) is a sectional view of a conventional bipolar transistor, and FIG. 2(b) is a sectional view of a bipolar transistor of this embodiment.

For the conventional bipolar transistor shown in FIG. 2(a), the equivalent circuit from the base layer 3 to the semiconductor substrate 1 is expressed by serial connection of a depletion layer resistance 12 (R_{d}) near the side wall of a depletion layer region 11 between the base layer 3 and the collector layer 4 and a collector layer resistance 13 (R_{c}) of the collector layer 2. When the collector-base voltage is taken as V_{CB} and the leakage current as I_{C}, the following equation holds.

V_{CB}=I_{C}(R_{d}+R_{c}) (1)

Also, since the depletion layer resistance R_{d} is far higher than the collector layer resistance R_{c} (R_{d}>>R_{c}) in Eq.(1), a voltage V_{dep} applied to the depletion layer region 11 near the side wall is expressed as

V_{dep}=I_{C}·R_{d}≈I_{C}(R_{d}+R_{c})=V_{CB} (2)

Eq.(2) indicates that the voltage V_{dep} applied to the depletion layer region 11 is approximately equal to the collector-base voltage V_{CB}.

On the other hand, for the bipolar transistor of this embodiment shown in FIG. 2(b), a collector surface resistance 15 (R_{CS}), which is a resistance due to the conductive film 8, and a base-collector surface resistance 14 (R_{CB}) at the base-collector interface are added to the collector layer resistance 13 (R_{c}) and the depletion layer resistance 12 (R_{d}) near the side wall, respectively. Therefore, the voltage V_{dep} applied to the depletion layer region 11 is expressed as

$${V}_{dep} = \frac{{V}_{CB} {R}_{d} {{R}_{CB} ( {R}_{d} + {R}_{CB} )}^{- 1}}{{R}_{d} {{R}_{CB} ( {R}_{d} + {R}_{CB} )}^{- 1} + {R}_{CS} {{R}_{C} ( {R}_{CS} + {R}_{C} )}^{- 1}} \qquad ( 3 )$$

Also, since R_{d}>>R_{CB} and R_{c} R_{CS}, Eq.(3) can be approximated as

V_{dep}=V_{CB}R_{CB}/(R_{CB}+R_{CS}) (4)

In Eq.(4), the voltage V_{dep} applied to the depletion layer region 11 is compared with the collector-base voltage V_{CB}. Since the resistance of the conductive film 8 is uniform, and the longitudinal length of the surface portion of the collector-base interface is overwhelmingly larger than the longitudinal length of the surface portion of the collector layer 2, the following equation holds.

R_{CB}<<R_{CS} (5)

Therefore, from Eq.(4),

V_{dep}<<R_{CB} (6)

is derived. Eq.(6) indicates that the voltage V_{dep} applied to the depletion layer region 11 is far smaller than the collector-base voltage V_{CB}, so that the electric field applied to the depletion layer region 11 is relaxed.

The aforementioned depletion layer resistance R_{d} is a virtual resistance determined from R_{d}=V/I by a leakage current I produced when a certain voltage V is applied to between the base and the collector.

Thus, according to this embodiment, by forming the conductive film 8 in such a manner as to be in contact with the side wall of the transistor, the electric field applied to the depletion layer region 11 near the side wall can be relaxed, so that the withstand voltage of transistor can be increased.

Also the electric field concentration on the side wall of transistor can be relaxed by the conductive film 8. Therefore, a decrease in current amplification factor due to the Kirk effect can be prevented.

Further, since the conductive film 8 is formed on the side wall of transistor, there is no need for providing a guard ring etc. by extending the outer peripheral portion of the collector layer 2. Therefore, the effective area of transistor is increased, so that the maximum current capable of being switched can be increased.

The following is a description of an example of the high-power bipolar transistor. In this example, the high-power bipolar transistor shown in FIG. 1 was formed into a chip measuring 4 mm×4 mm, and the areas of the emitter electrode 5 and the base electrode 6 were made 0.1 cm² and 0.06 cm², respectively. Also, the collector electrode 7 was formed all over the back of the n-type semiconductor substrate 1. The conductivity type, dope concentration, and thickness of each layer are given in Table 1.

TABLE 1
Characteristic table for each layer of transistor of
this example

| | Conductivity | | Dope |
|---|---|---|---|
| Function | type | Thickness | concentration |
| Emitter | n | 0.6 μm | 1 × 10²⁰/cm³ |
| Base | p | 0.4 μm | 2 × 10¹⁷/cm³ |
| Collector | n | 20 μm | 1 × 10¹⁴/cm³ |
| Substrate | n | 550 μm | 8 × 10¹⁹/cm³ |

Also, the side face of the high-power bipolar transistor of this example is cut at an angle of 90 degrees with the n-type semiconductor substrate 1. The side face is subjected to etching of several tens of angstroms, and the conductive film 8 of amorphous silicon is stacked on the surface thereof by, for example, the plasma CVD process. The thickness of amorphous silicon is 0.1 μm or smaller. Impurities such as phosphorus (P) are doped in a very small amount of 10¹⁴/cm³ or smaller, and the resistivity is about 100 to 1000 Ω·cm. Therefore, the conductive film 8 does not produce a short circuit between the base and the collector, but it is a high-resistance film such as to relax the electric field concentration to the base-collector depletion layer near the side wall.

Next, in order to compare the characteristics of the bipolar transistor of this example formed with the conductive film 8 on the side wall with those of the conventional bipolar transistor with no conductive film, a reverse bias voltage is applied to between the collector and the base of each of the transistors, and a voltage producing a leakage current of 1 mA was evaluated as a withstand voltage. As a result, a withstand voltage of about 350 V was obtained in this example, while the conventional transistor had a withstand voltage of about 280 V.

Thus, according to the high-power bipolar transistor of this example, by covering the side wall of transistor with the conductive film 8, the electric field concentration on the side wall of transistor can be relaxed, so that the withstand voltage can be increased.

Also, since the electric field concentration on the side wall of transistor can be relaxed by the conductive film 8, the thickness of the collector layer 2 is decreased, so that a decrease in current amplification factor due to the Kirk effect can be prevented.

Furthermore, since the side wall of the collector layer 2 can be at approximately 90 degrees with the semiconductor substrate 1, there is no need for providing a guard ring etc. by extending the outer peripheral portion of the collector layer 2. Therefore, the effective area of transistor is increased, so that the maximum current capable of being switched can be increased.

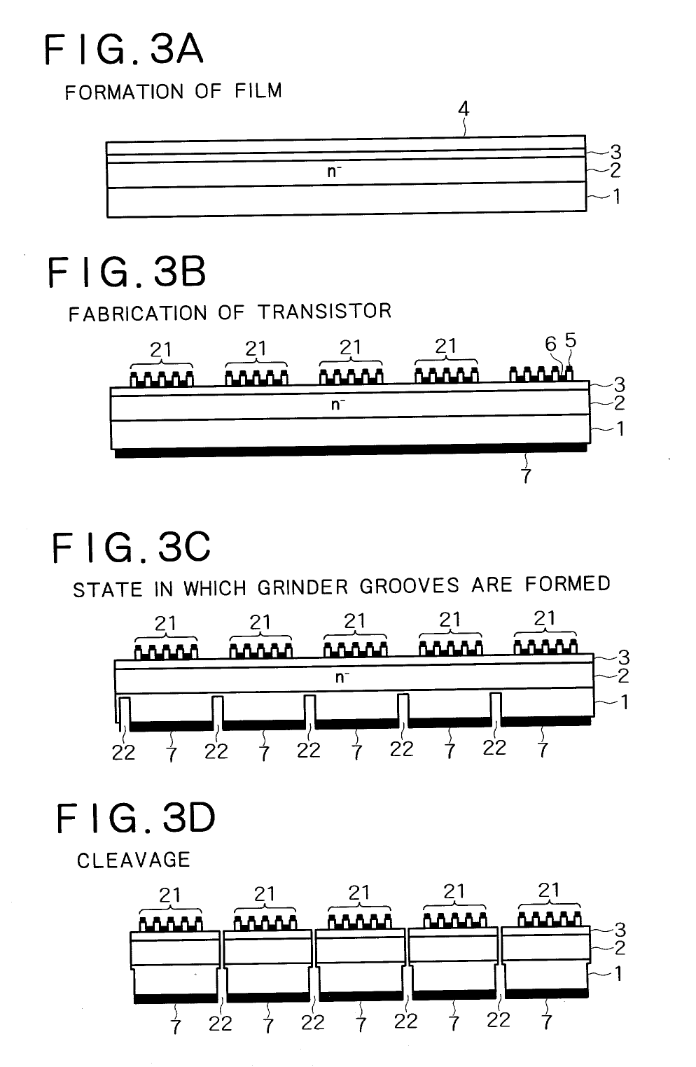

Next, a process for manufacturing a high-power bipolar transistor in accordance with an embodiment will be described with reference to FIG. 3. In the manufacturing process in accordance with this embodiment, as shown in FIG. 3(a), the collector layer 2 of an n⁻-type semiconductor, the base layer 2 of a p-type semiconductor, and the emitter layer 4 of an n-type semiconductor are successively stacked on the silicon substrate 1 with a 5-inch diameter in the plane orientation (100).

For example, an n⁻-type silicon layer of 20 μm is stacked as the collector layer 2 on the silicon substrate 1 with a thickness of 550 μm, a p-type silicon layer of 0.4 μm is stacked thereon as the base layer 3, and further an n-type silicon layer of 0.6 μm is stacked thereon as the emitter layer 4.

Next, this lamination is subjected to fabrication such as etching and patterning, by which the emitter electrode 5, the base electrode 6, and the collector electrode 7 are formed as shown in FIG. 3(b). In this case, transistor portions 21 each formed of a set of the emitter electrode 5 and the base electrode 6 are formed in an array form with intervals of about 100 μm. The conductivity type, dope concentration, and thickness of each layer are the same as the values given in Table 1.

Next, as shown in FIG. 3(c), grinder grooves 22 are formed by using a rotary grinder from the back side of the silicon substrate 1, that is, from the side on which the collector electrode 7 is provided. In this case, the depth of the grinder groove 22 is set so that the groove is within the silicon substrate 1 and does not reach the collector layer 2. The depth of the grinder groove 22 is, for example, about 530 μm.

Thus, according the manufacturing method in accordance with this embodiment, the grinder groove 22 is formed within the silicon substrate only, and does not reach the collector layer 2, the base layer 3, and the emitter layer 4. Therefore, the metamorphism due to the grinder groove 22 does not have an influence on the characteristics of transistor.

Therefore, unlike the conventional manufacturing method, there is no need for forming a mesa groove or a buffer region at the outer periphery of the transistor portion 21 to avoid the metamorphism due to the grinder groove 22. Thereby, the effective area of transistor is increased, so that the maximum current capable of being switched can be increased.

Next, as shown in FIG. 3(d), cleavage is made along the grinder groove 22 to cut out the transistor portion 21. In this case, if a cutout groove is formed in the direction parallel to the plane orientation (111) (easy-to-cleave direction), the cleavage is easy to make by means of the grinder groove 22, so that the fractured section of cleavage has no irregularities, and thus the yield can be increased. Alternatively, etching can be performed along the grinder groove 22 to separate the transistor portions 21 from each other.

Thus, according to the manufacturing method in accordance with this embodiment, in the transistor cutting-out process, there is no need for forming a buffer region for avoiding the metamorphism due to a mesa groove or grinding. Therefore, the effective area of transistor is increased, so that the maximum current capable of being switched can be increased.

Although the npn⁻n⁺ type bipolar transistor has been described in the above-described embodiments, the present invention can be applied to a pnp⁻p⁺ type bipolar transistor having reversed conductivity.

Also, the scope of protection of the present invention is not limited to the above-described embodiments, and embraces the inventions described in the appended claims and the equivalents thereof.

As described above, according to the present invention, since the conductive film covering the side faces of the collector layer and base layer is provided, the electric field concentration near the side faces of the collector layer and base layer is relaxed, so that the withstand voltage of transistor can be increased. Also, since the thickness of the collector layer can be decreased, the current amplification factor can be enhanced.

Also, since the side faces of the collector layer and base layer are at an angle of approximately 90 degrees with the interface between the collector layer and the semiconductor substrate, the effective area of transistor is increased, so that the maximum current capable of being switched can be increased.

Further, since the separation groove is formed within the semiconductor substrate from the back side of the semiconductor substrate to separate a set of the base electrode and emitter electrode along the separation groove, the metamorphism due to the separation groove formed by a grinder or the like does not affect the collector layer, base layer, and emitter layer. Therefore, there is no need for forming a region for avoiding the metamorphism due to the separation groove at the outer periphery of the transistor. As a result, the effective area of transistor is increased, so that the maximum current capable of being switched can be increased.

1. A bipolar transistor comprising:
a first conductivity type semiconductor substrate;
a first conductivity type collector layer with an impurity concentration lower than that of said semiconductor substrate, which is formed on said semiconductor substrate;
a second conductivity type base layer formed on said collector layer;
a first conductivity type emitter layer formed on said base layer; and
a conductive film covering the side faces of said collector layer and base layer.

2. The bipolar transistor according to claim 1, wherein the side faces of said collector layer and base layer are at an angle of approximately 90 degrees with the interface between said collector layer and said semiconductor substrate.

3. The bipolar transistor according to claim 1, wherein said conductive film is formed of amorphous silicon with a resistivity of 100 to 1000 Ω·cm.

4. The bipolar transistor according to claim 3, wherein said conductive film has a thickness of 0.1 μm or smaller.

5. A manufacturing method for a bipolar transistor, comprising the steps of:
forming a first conductivity type collector layer with an impurity concentration lower than that of a first conductivity type semiconductor substrate, a second conductivity type base layer, and a first conductivity type emitter layer on the surface of said first conductivity type semiconductor substrate;
forming a plurality of sets of a base electrode and an emitter electrode at intervals on said base layer and emitter layer;
forming separation grooves in said semiconductor substrate between the adjacent sets of the base electrode and emitter electrode from the back side of said semiconductor substrate; and
separating said sets of the base electrode and emitter electrode from each other along said separation groove.

6. The manufacturing method for a bipolar transistor according to claim 5, wherein said sets of the base electrode and emitter electrode are subjected to cleavage or etching along said separation groove.
